(19) United States
(12) Patent Application Publication
(10) Pub. No.: US 2020/0279783 A1
(43) Pub. Date: Sep. 3, 2020

(54) PROCESS CONTROL OF SEMICONDUCTOR FABRICATION BASED ON LINKAGE BETWEEN DIFFERENT FABRICATION STEPS

(71) Applicants: GLOBALFOUNDRIES INC., Grand Cayman (KY); NOVA MEASURING INSTRUMENTS LTD., Rehovot (IL)

(72) Inventors: PADRAIG TIMONEY, CLIFTON PARK, NY (US); TAHER KAGALWALA, CLIFTON PARK, NY (US); ALOK VAID, CLIFTON PARK, NY (US); SRIDHAR MAHENDRAKAR, CLIFTON PARK, NY (US); DHAIRYA DIXIT, CLIFTON PARK, NY (US); SHAY YOGEV, KIBBUTZ KFAR MENACHEM (IL); MATTHEW SENDELBACH, FISHKILL, NY (US); CHARLES KANG, SANTA CLARA, CA (US)

(21) Appl. No.: 16/288,152

(22) Filed: Feb. 28, 2019

(51) Int. Cl. H01L 21/66; G01N 21/956; H01L 29/66; G01N 21/95

(52) U.S. Cl. CPC H01L 22/12; G01N 21/9501; H01L 29/66795; G01N 21/956

(57) ABSTRACT

Process control during manufacture of semiconductor devices by collecting scatterometric spectra of a FinFET reference fin structure on a reference semiconductor wafer at a first checkpoint proximate to a first processing step during fabrication of the reference semiconductor wafer, collecting reference measurements of the reference fin structure at a second checkpoint proximate to a second processing step subsequent to the first checkpoint, and performing machine learning to identify correspondence between the scatterometric spectra and values based on the reference measurements and train a prediction model for producing a prediction value associated with a corresponding production fin structure of the FinFET on a production semiconductor wafer based on scatterometric spectra of the production fin structure collected at the corresponding first checkpoint during fabrication of the production semiconductor wafer.

### BACKGROUND

Metrology is typically employed during fabrication of structures on semiconductor wafers in order to monitor and control the fabrication process. Measurements of structural characteristics, such as critical dimension (CD), sidewall angle (SWA), height, and trench depth taken at various processing steps provide information such as whether or not a processing step produces an acceptable result, as well as metrics such as etch rate and deposition rate. Such measurements that are taken at a later processing step when manufacturing a given wafer often indicate a problem that could have been corrected at an earlier processing step. While this information may be used to adjust the earlier processing step for subsequently fabricated wafers, this is too late for the given wafer if the problem results in a defect in the given wafer that cannot subsequently be corrected.

### SUMMARY

In one aspect of the invention a computer-implemented method is provided for use in process control during manufacture of semiconductor devices on semiconductor wafers, the method including collecting scatterometric spectra of a reference fin structure of a FinFET on a reference semiconductor wafer at a first checkpoint proximate to a first processing step during fabrication of the reference semiconductor wafer, collecting reference measurements of the reference fin structure at a second checkpoint proximate to a second processing step during the fabrication of the reference semiconductor wafer, where the second checkpoint is subsequent to the first checkpoint, and performing machine learning to identify correspondence between the scatterometric spectra and values based on the reference measurements, thereby training a prediction model for producing a prediction value associated with a production fin structure of the FinFET on a production semiconductor wafer based on scatterometric spectra of the production fin structure collected at a first checkpoint during fabrication of the production semiconductor wafer, where the production fin structure corresponds to the reference fin structure, and where the first checkpoint during the fabrication of the production semiconductor wafer corresponds to the first checkpoint during the fabrication of the reference semiconductor wafer.

In another aspect of the invention the method further includes collecting the scatterometric spectra of the production fin structure at the first checkpoint during the fabrication of the production semiconductor wafer, and producing, using the prediction model, the prediction value associated with the production fin structure based on scatterometric spectra of the production fin structure.

In another aspect of the invention the method further includes producing the prediction value at the first checkpoint during the fabrication of the production semiconductor wafer.

In another aspect of the invention the prediction value is predictive of an expected measurement of the production fin structure at a second checkpoint during the fabrication of the production semiconductor wafer corresponding to the second checkpoint during the fabrication of the reference semiconductor wafer.

In another aspect of the invention the method further includes comparing the expected measurement with a predefined target measurement planned for the production fin structure at the second checkpoint during the fabrication of the production semiconductor wafer, and adjusting a process control parameter of a processing step subsequent to the first checkpoint during the fabrication of the production semiconductor wafer and prior to the second checkpoint during the fabrication of the production semiconductor wafer, to reduce a difference between the expected measurement and the predefined target measurement.

In another aspect of the invention the comparing includes comparing at the first checkpoint during the fabrication of the production semiconductor wafer.

In another aspect of the invention the adjusting includes providing input to a semiconductor manufacturing tool for controlling operation of the semiconductor manufacturing tool during the fabrication of the production semiconductor wafer.

In another aspect of the invention the performing machine learning includes identifying the correspondence between the scatterometric spectra and the values based on the reference measurements where predefined statistical criteria are met indicating that any of the scatterometric spectra of the reference fin structure at the first checkpoint are statistically linked to any of the values based on the reference measurements of the reference fin structure at the second checkpoint.

In another aspect of the invention the fabrication of the production semiconductor wafer and the production fin structure uses a process identical to a process used to fabricate the reference semiconductor wafer and the reference fin structure, where the first and second checkpoints during the fabrication of the production semiconductor wafer correspond, respectively, to the first and second checkpoints during the fabrication of the reference semiconductor wafer.

In another aspect of the invention the method further includes determining, using the scatterometric spectra of the production fin structure, a height difference between a top of the production fin structure and a top of a silicon oxide layer above a trench adjacent to the production fin structure, calculating a total etch amount by adding the expected measurement to the height difference, converting the total etch amount to an etch time, and controlling one or more processing steps after the first checkpoint during the fabrication of the production semiconductor wafer to implement the etch time in order to achieve a predefined target measurement planned for the production fin structure at the second checkpoint during the fabrication of the production semiconductor wafer, where the expected measurement and the predefined target measurement are of height of the production fin structure.

In another aspect of the invention the method further includes comparing the expected measurement with the predefined target measurement, and adjusting the etch time to reduce a difference between the expected measurement and the predefined target measurement.

In another aspect of the invention the method further includes determining, using the scatterometric spectra of the reference fin structure, a height difference between a top of the reference fin structure and a top of a silicon oxide layer above a trench adjacent to the reference fin structure, where the reference measurement is of height of the reference fin structure, calculating a total etch amount by adding the reference measurement to the height difference, where the total etch amount is used as one of the values based on the reference measurements used to train the prediction model, collecting the scatterometric spectra of the production fin structure at the first checkpoint during the fabrication of the production semiconductor wafer, producing, using the prediction model, the prediction value representing a total etch amount associated with the production fin structure based on scatterometric spectra of the production fin structure, converting the total etch amount to an etch time, and controlling one or more processing steps after the first checkpoint during the fabrication of the production semiconductor wafer to implement the etch time in order to achieve a predefined target measurement at the second checkpoint during the fabrication of the reference semiconductor wafer, where the predefined target measurement is of height of the production fin structure.

In another aspect of the invention the method further includes determining an expected fin height at the second checkpoint from the etch time, comparing the expected fin height with the predefined target measurement, and adjusting the etch time to reduce a difference between the expected fin height and the predefined target measurement.

In another aspect of the invention a system is provided for use in process control during manufacture of semiconductor devices on semiconductor wafers, the system including a spectrum acquisition tool configured to collect scatterometric spectra of a reference fin structure of a FinFET on a reference semiconductor wafer at a first checkpoint proximate to a first processing step during fabrication of the reference semiconductor wafer, a reference tool configured to collect reference measurements of the reference fin structure at a second checkpoint proximate to a second processing step during the fabrication of the reference semiconductor wafer, where the second checkpoint is subsequent to the first checkpoint, and a training unit configured to perform machine learning to identify correspondence between the scatterometric spectra and values based on the reference measurements, thereby training a prediction model for producing a prediction value associated with a production fin structure of the FinFET on a production semiconductor wafer based on scatterometric spectra of the production fin structure collected at a first checkpoint during fabrication of the production semiconductor wafer, where the production fin structure corresponds to the reference fin structure, and where the first checkpoint during the fabrication of the production semiconductor wafer corresponds to the first checkpoint during the fabrication of the reference semiconductor wafer.

In another aspect of the invention the spectrum acquisition tool is configured to collect the scatterometric spectra of the production fin structure at the first checkpoint during the fabrication of the production semiconductor wafer, and further includes a prediction unit configured to produce, using the prediction model, the prediction value associated with the production fin structure based on scatterometric spectra of the production fin structure.

In another aspect of the invention the prediction unit is configured to produce the prediction value at the first checkpoint during the fabrication of the production semiconductor wafer.

In another aspect of the invention the prediction value is predictive of an expected measurement of the production fin structure at a second checkpoint during the fabrication of the production semiconductor wafer corresponding to the second checkpoint during the fabrication of the reference semiconductor wafer.

In another aspect of the invention the system further includes a process control unit configured to compare the expected measurement with a predefined target measurement planned for the production fin structure at the second checkpoint during the fabrication of the production semiconductor wafer, and adjust a process control parameter of a processing step subsequent to the first checkpoint during the fabrication of the production semiconductor wafer and prior to the second checkpoint during the fabrication of the production semiconductor wafer, to reduce a difference between the expected measurement and the predefined target measurement.

In another aspect of the invention the training unit is configured to perform the machine learning to identify the correspondence between the scatterometric spectra and the values based on the reference measurements where predefined statistical criteria are met indicating that any of the scatterometric spectra of the reference fin structure at the first checkpoint are statistically linked to any of the values based on the reference measurements of the reference fin structure at the second checkpoint.

In another aspect of the invention the spectrum acquisition tool is configured to determine, using the scatterometric spectra of the production fin structure, a height difference between a top of the production fin structure and a top of a silicon oxide layer above a trench adjacent to the production fin structure, and the process control unit is configured to calculate a total etch amount by adding the expected measurement to the height difference, convert the total etch amount to an etch time, and control one or more processing steps after the first checkpoint during the fabrication of the production semiconductor wafer to implement the etch time in order to achieve a predefined target measurement planned for the production fin structure at the second checkpoint during the fabrication of the production semiconductor wafer, where the expected measurement and the predefined target measurement are of height of the production fin structure.

In another aspect of the invention the spectrum acquisition tool is configured to determine, using the scatterometric spectra of the reference fin structure, a height difference between a top of the reference fin structure and a top of a silicon oxide layer above a trench adjacent to the reference fin structure, where the reference measurement is of height of the reference fin structure, the training unit is configured to use a total etch amount as one of the values based on the reference measurements used to train the prediction model, where the total etch amount is calculated by adding the reference measurement to the height difference, the spectrum acquisition tool is configured to collect the scatterometric spectra of the production fin structure at the first checkpoint during the fabrication of the production semiconductor wafer, the prediction unit is configured to produce, using the prediction model, the prediction value representing a total etch amount associated with the production fin structure based on scatterometric spectra of the production fin structure, and the process control unit is configured to convert the total etch amount to an etch time, and control one or more processing steps after the first checkpoint during the fabrication of the production semiconductor wafer to implement the etch time in order to achieve a predefined target measurement at the second checkpoint during the fabrication of the reference semiconductor wafer, where the predefined target measurement is of height of the production fin structure.

In another aspect of the invention the process control unit is configured to determine an expected fin height at the second checkpoint from the etch time, compare the expected fin height with the predefined target measurement, and adjust the etch time to reduce a difference between the expected fin height and the predefined target measurement.

### BRIEF DESCRIPTION OF THE DRAWINGS

Aspects of the invention will be understood and appreciated more fully from the following detailed description taken in conjunction with the appended drawings in which:

FIGS. 1A and 1B, taken together, is a simplified conceptual illustration of a system for predictive process control of semiconductor fabrication, constructed and operative in accordance with an embodiment of the invention;

FIGS. 2A and 2B are simplified conceptual illustrations of a FinFET fin structure at different processing steps during FinFET fabrication, useful in understanding an embodiment of the invention;

FIGS. 3A and 3B are simplified conceptual illustrations of a FinFET fin structure at different processing steps during FinFET fabrication, useful in understanding additional embodiments of the invention; and

FIGS. 4-6 are simplified flowchart illustrations of exemplary methods of operation of the system of FIGS. 1A and 1B, operative in accordance with various embodiments of the invention.

### DETAILED DESCRIPTION

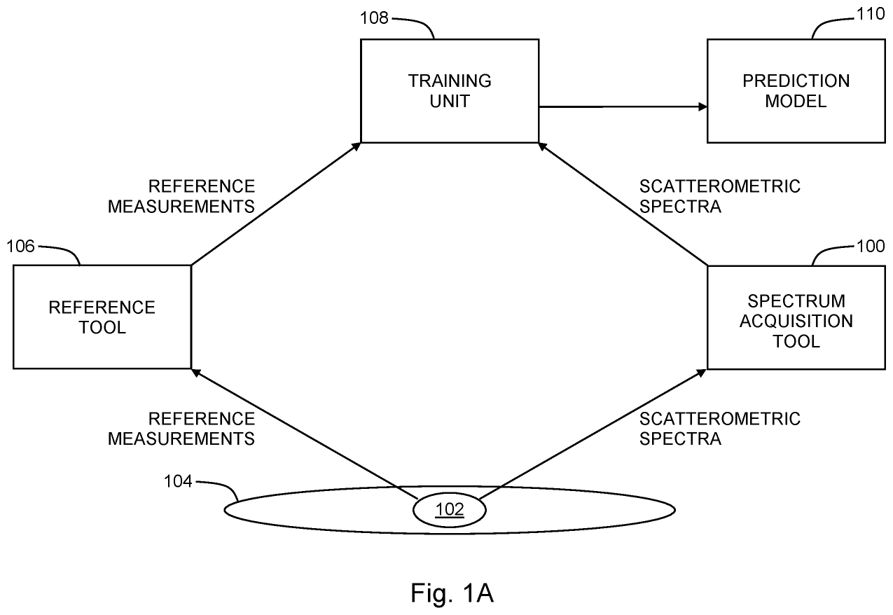

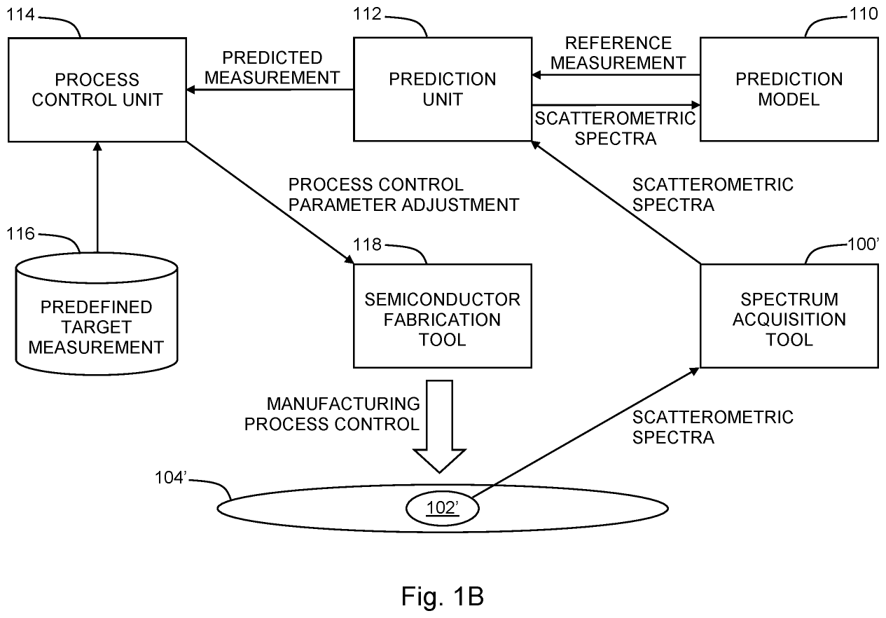

Reference is now made to FIGS. 1A and 1B, which, taken together, is a simplified conceptual illustration of a system for predictive process control of semiconductor fabrication, constructed and operative in accordance with an embodiment of the invention. In FIG. 1A, a spectrum acquisition tool 100, such as a Spectral Ellipsometer (SE), a Spectral Reflectometer (SR), or a Polarized Spectral Reflectometer, is employed to collect, in accordance with conventional techniques, scatterometric spectra of a reference structure, such as fin structure 102 of a Fin Field-effect transistor (FinFET), on a reference semiconductor wafer 104, such as by performing spectrum photometry on reference fin structure 102. Spectrum acquisition tool 100 collects the scatterometric spectra of reference fin structure 102 at a first checkpoint proximate to a selected processing step during fabrication of reference semiconductor wafer 104, such as just after completion of a given etch step. Any processing step may be selected for the first checkpoint provided that it is followed by one or more later processing steps.

A reference tool 106, such as a Critical Dimension Scanning Electron Microscope (CD-SEM), an Atomic Force Microscope (AFM), or a Critical Dimension Atomic Force Microscope (CD-AFM), is employed to collect, in accordance with conventional techniques, reference measurements of reference fin structure 102 on reference semiconductor wafer 104 at a second checkpoint proximate to a different processing step during fabrication of reference semiconductor wafer 104, such as just after completion of a different etch step, where the second checkpoint is subsequent to the first checkpoint during the fabrication process. The reference measurements may be any type of measurements of, or relative to, reference fin structure 102, such as critical dimension (CD), sidewall angle (SWA), height, and trench depth. The processing step to which the second checkpoint is proximate and the processing step to which the first checkpoint is proximate may be separated by zero or more intermediate processing steps.

Spectrum acquisition tool 100 and reference tool 106 preferably obtain multiple scatterometric spectra and reference measurements for multiple reference fin structures 102 on one or more reference semiconductor wafers 104.

A training unit 108 is configured to train a prediction model 110 by performing machine learning (ML) to identify correspondence between the scatterometric spectra and values based on the reference measurements, such as the reference measurements themselves or values derived therefrom. Training unit 108 may employ any known ML technique suitable for identifying such correspondence between the scatterometric spectra and the values based on the reference measurements where predefined statistical criteria are met indicating that particular scatterometric spectra of a given reference fin structure 102 at the first checkpoint are statistically linked to particular value based on the reference measurements of the given reference fin structure 102 at the second checkpoint. Prediction model 110 is provided for use with process control apparatus configured to control manufacture of semiconductor devices on semiconductor wafers, as is now described with reference to FIG. 1B.

In FIG. 1B, a spectrum acquisition tool 100′, which may be spectrum acquisition tool 100 or another similar or identical spectrum acquisition tool, is employed during a production process, such as during a high-volume manufacturing (HVM) process of fabricating semiconductor devices on semiconductor wafers, to collect scatterometric spectra of a production fin structure 102′ of a FinFET on a production semiconductor wafer 104′, where production fin structure 102′ corresponds to reference fin structure 102, and where the spectra are obtained in the manner described above with reference to spectrum acquisition tool 100 in FIG. 1A. The process used to fabricate production semiconductor wafer 104′ and production fin structure 102′ is preferably identical to the process described in FIG. 1A that is used to fabricate reference semiconductor wafer 104 and reference fin structure 102, such that the first and second checkpoints referred to in the description of FIG. 1A correspond, respectively, to the same points during the process used to fabricate production semiconductor wafer 104′ and production fin structure 102′.

In FIG. 1B spectrum acquisition tool 100′ collects the scatterometric spectra of production fin structure 102′ at the first checkpoint during fabrication of production semiconductor wafer 104′. A prediction unit 112 employs prediction model 110 to produce, preferably also at the first checkpoint, a prediction value associated with production fin structure 102′ at the second checkpoint during fabrication of production semiconductor wafer 104′. Prediction unit 112 produces the prediction value by identifying a value based on a reference measurement in prediction model 110 that corresponds to the scatterometric spectra of production fin structure 102′ collected at the first checkpoint, and then using the identified value as the prediction value. The prediction value is predictive of an expected measurement of production fin structure 102′ at the second checkpoint, but that is produced in advance of the second checkpoint, such as at the first checkpoint, during fabrication of production semiconductor wafer 104′.

A process control unit 114, which may be any known process control hardware and/or software for controlling the process of fabricating semiconductor devices on semiconductor wafers, is configured to compare, preferably at the first checkpoint during fabrication of the production semiconductor wafer 104′, the expected measurement of production fin structure 102′ with a predefined target measurement 116 planned for production fin structure 102′ at the second checkpoint during fabrication of production semiconductor wafer 104′. Process control unit 114 is also configured to adjust, in accordance with predefined adjustment protocols, one or more process control parameters, such as etch time or deposition rate, of one or more processing steps subsequent to the first checkpoint during fabrication of production semiconductor wafer 104′ and prior to the second checkpoint during fabrication of production semiconductor wafer 104′, to reduce a difference between the expected measurement and the predefined target measurement, if such a difference is found. Process control unit 114 preferably effects such adjustments by providing, in accordance with conventional techniques, input to any known semiconductor manufacturing tool 118 (e.g., lithography tool, etch tool, deposition tool, etc.) for controlling operation of the tool during the fabrication of production semiconductor wafer 104′.

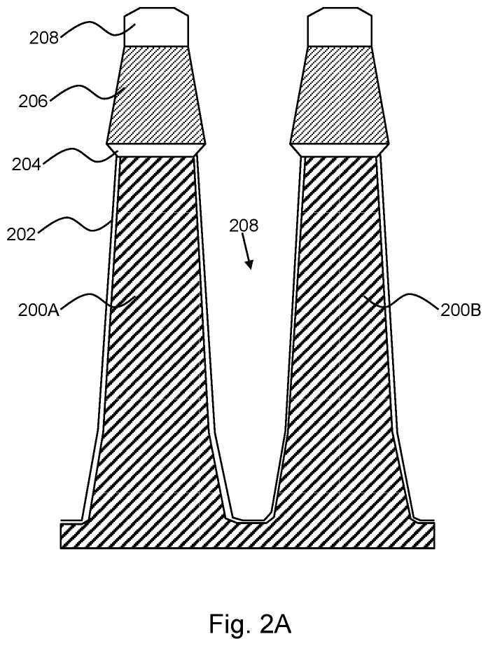

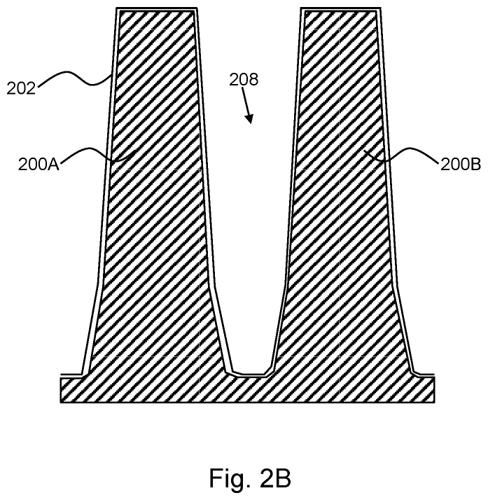

Operation of the systems of FIGS. 1A and 1B may be illustrated by way of example with reference to FIG. 2A, which shows silicon fin structures 200A-200B of a FinFET at a first checkpoint during their fabrication, and FIG. 2B, which shows fin structures 200A-200B at a second checkpoint subsequent to the first checkpoint during the fabrication process. In FIG. 2A the sidewalls of fin structures 200A-200B are shown covered in a layer 202 of silicon oxide. The top of fin structures 200A-200B is also capped with a layer 204 of silicon oxide, atop which sits a layer of silicon nitride 206 below yet another layer 208 of silicon oxide. Fin structure 200A is separated from fin structure 200B by an air-filled trench 210, such as may be formed in accordance with conventional shallow trench isolation (STI) techniques. In FIG. 2B, fin structures 200A-200B is shown after an etch processing step has removed layers 204, 206, and 208.

The system of FIG. 1A collects, on one or more reference semiconductor wafers, scatterometric spectra of fin structures 200A-200B at the first checkpoint shown in FIG. 2A, and thereafter collects reference measurements of the critical dimension (CD) of fin structures 200A-200B at the second checkpoint shown in FIG. 2B. Using the scatterometric spectra and reference measurements, the system of FIG. 1A trains prediction model 110 to identify various scatterometric spectra of fin structures 200A-200B at the first checkpoint that are statistically linked to various reference measurements of fin structures 200A-200B at the second checkpoint.

At the first checkpoint during fabrication of fin structures 200A-200B on a production semiconductor wafer, the system of FIG. 1B collects scatterometric spectra of fin structures 200A-200B as shown in FIG. 2A and uses prediction model 110 to produce a prediction value representing an expected CD measurement of fin structures 200A-200B at the second checkpoint using the production scatterometric spectra just collected at the first checkpoint. Prediction model 110 is used to produce the expected CD measurement by identifying a prediction value in prediction model 110 that corresponds to the scatterometric spectra of production fin structures 200A-200B collected at the first checkpoint, and then using the identified prediction value as the expected CD measurement. The system of FIG. 1B then compares, at the first checkpoint, the expected CD measurement with a predefined target CD measurement planned for fin structures 200A-200B at the second checkpoint. If no difference is found between the expected CD measurement and the predefined target CD measurement, the fabrication process continues to the second checkpoint without adjustment. If a difference is found, the system of FIG. 1B adjusts, in accordance with predefined adjustment protocols, one or more process control parameters of one or more processing steps of the production fabrication process between the first and second checkpoints, in order to reduce the difference and thereby achieve the predefined target CD measurement at the second checkpoint.

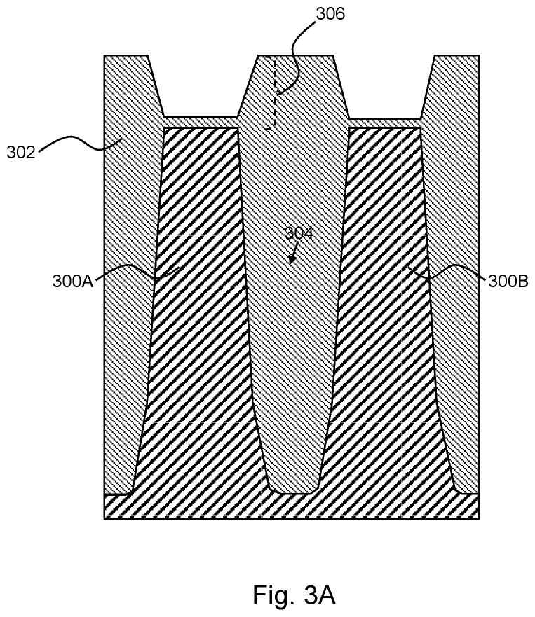

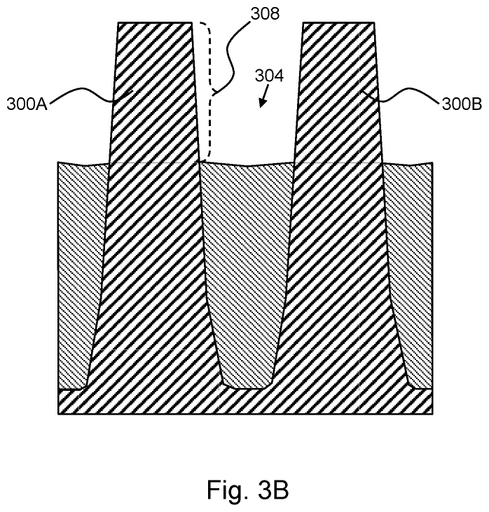

Operation of the systems of FIGS. 1A and 1B may be illustrated by way of another example with reference to FIGS. 3A and 3B, which show silicon fin structures 300A-300B of a FinFET at first and second checkpoints, respectively, during their fabrication. In FIG. 3A fin structures 300A-300B are shown at the first checkpoint completely covered in a layer 302 of silicon oxide, where the height difference between the top of the silicon oxide layer above trench 304 and the top of fin structures 300A-300B, indicated by reference numeral 306, is referred to herein as the STI step height. FIG. 3B shows fin structures 300A-300B at the second checkpoint after a portion of the silicon oxide has been etched away to reveal an upper portion of fin structures 300A-300B, where the height difference between the top of fin structures 300A-300B and the top of the post-etch silicon oxide layer in trench 304 is referred to herein as the fin height, indicated by reference numeral 306.

In one embodiment, the system of FIG. 1A collects, on one or more reference semiconductor wafers, scatterometric spectra of fin structures 300A-300B at the first checkpoint shown in FIG. 3A, and thereafter collects reference measurements of the fin height of fin structures 300A-300B at the second checkpoint shown in FIG. 3B. The system of FIG. 1A then uses the scatterometric spectra and reference measurements to train prediction model 110 as described hereinabove.

At the first checkpoint during fabrication of fin structures 300A-300B on a production semiconductor wafer, the system of FIG. 1B collects scatterometric spectra of fin structures 300A-300B as shown in FIG. 3A and uses prediction model 110 in the manner described above to produce a prediction value representing an expected fin height measurement of fin structures 300A-300B at the second checkpoint using the production scatterometric spectra just collected at the first checkpoint. The system of FIG. 1B also uses the production scatterometric spectra from the first checkpoint to determine the STI step height of fin structures 300A-300B in accordance with conventional techniques, such as by spectrum acquisition tool 100′ employing model-based Optical Critical Dimension (OCD) scatterometry. Process control unit 114 then compares, at the first checkpoint, the expected fin height measurement with a predefined target fin height measurement planned for fin structures 300A-300B at the second checkpoint. Process control unit 114 then calculates a total etch amount by adding the expected fin height measurement to the STI step height. Process control unit 114 then converts the total etch amount, in accordance with conventional techniques, to an etch time that process control unit 114 then applies to the production semiconductor wafer by controlling one or more processing steps after the first checkpoint to implement the etch time in order to achieve the predefined target fin height measurement. If no difference is found between the expected fin height measurement and the predefined target fin height measurement, the fabrication process continues to the second checkpoint without adjustment to the etch time. If a difference is found, process control unit 114 adjusts, in accordance with predefined adjustment protocols, the etch time (either directly or by first adjusting the total etch amount), in order to reduce the difference and thereby achieve the predefined target fin height measurement at the second checkpoint.

In an alternative embodiment, in addition to collecting, on one or more reference semiconductor wafers, scatterometric spectra at the first checkpoint shown in FIG. 3A and reference measurements of fin height at the second checkpoint shown in FIG. 3B, spectrum acquisition tool 100 also uses the scatterometric spectra from the first checkpoint to determine the STI step height of fin structures 300A-300B in accordance with conventional techniques, such as by employing model-based Optical Critical Dimension (OCD) scatterometry. The system of FIG. 1A then calculates a total etch amount by adding the reference fin height measurement to the STI step height, and uses various collected scatterometric spectra and calculated total etch amounts to train prediction model 110 to identify scatterometric spectra of fin structures 300A-300B at the first checkpoint that are statistically linked to total etch amounts calculated based on reference measurements of fin structures 300A-300B at the second checkpoint.

At the first checkpoint during fabrication of fin structures 300A-300B on a production semiconductor wafer, spectrum acquisition tool 100′ collects scatterometric spectra of fin structures 300A-300B as shown in FIG. 3A, and prediction unit 112 uses prediction model 110 to produce a prediction value representing a total etch amount by identifying a total etch amount in prediction model 110 that corresponds to the production scatterometric spectra of production fin structures 300A-300B collected at the first checkpoint. Process control unit 114 the converts the total etch amount to an etch time, from which an expected fin height at the second checkpoint is also determined, and which process control unit 114 applies to the production semiconductor wafer by controlling one or more processing steps after the first checkpoint to implement the etch time. Process control unit 114 compares, at the first checkpoint, the expected fin height measurement with a predefined target fin height measurement planned for fin structures 300A-300B at the second checkpoint. If no difference is found between the expected fin height measurement and the predefined target fin height measurement, the fabrication process continues to the second checkpoint without adjustment to the etch time. If a difference is found, process control unit 114 adjusts, in accordance with predefined adjustment protocols, the etch time (either directly or by first adjusting the total etch amount), in order to reduce the difference and thereby achieve the predefined target fin height measurement at the second checkpoint.

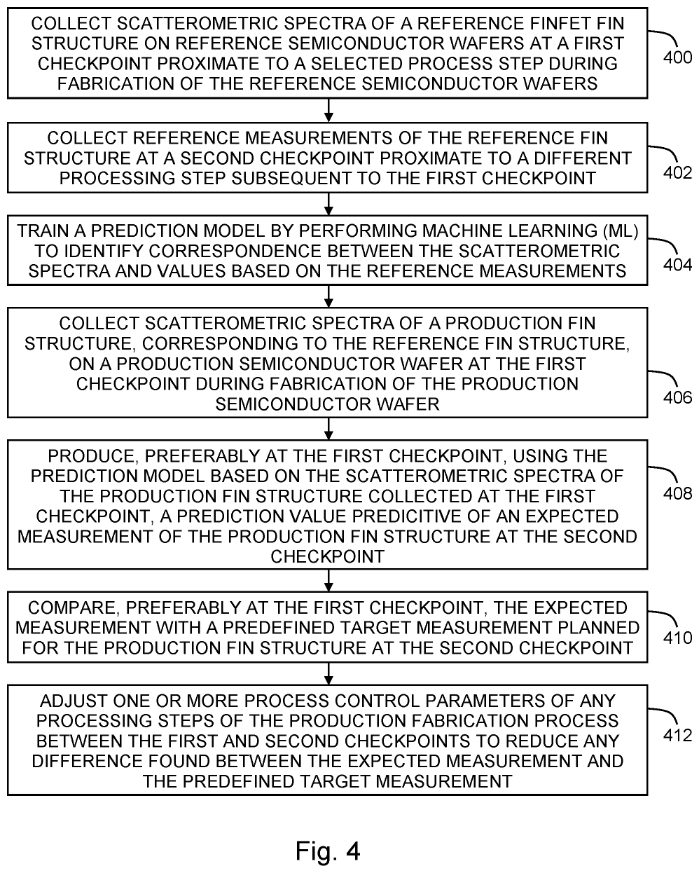

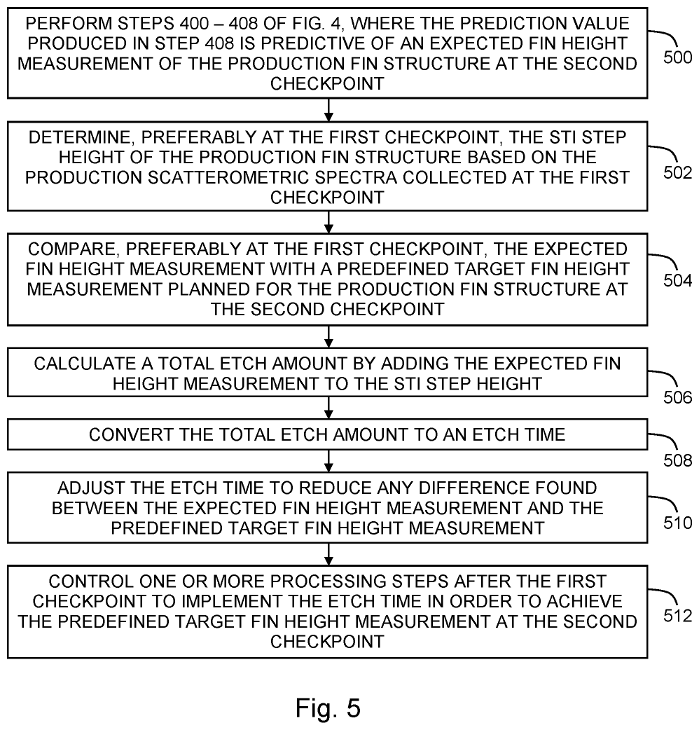

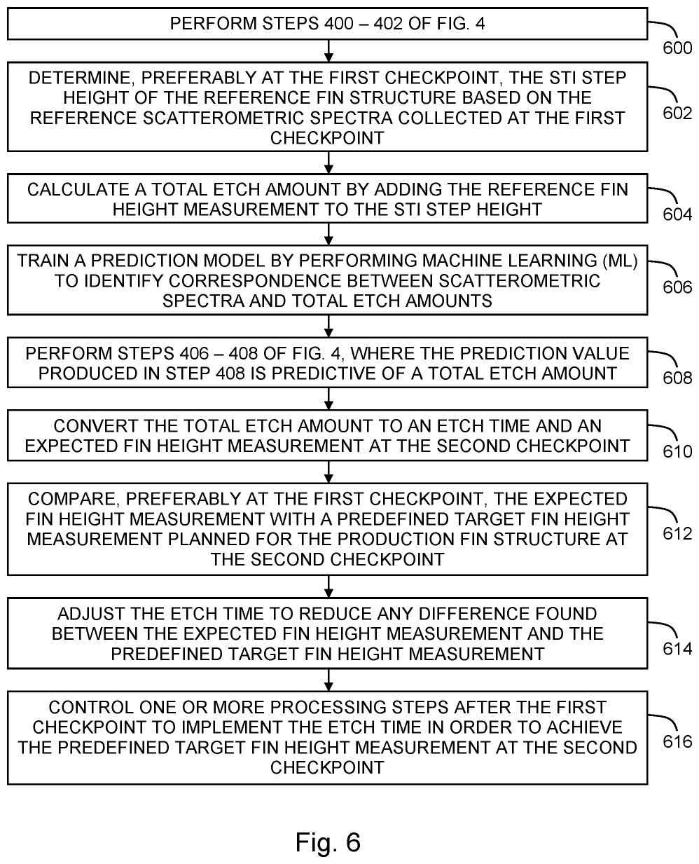

Reference is now made to FIG. 4 which is a simplified flowchart illustration of an exemplary method of operation of the system of FIGS. 1A and 1B, operative in accordance with an embodiment of the invention. In the method of FIG. 4, scatterometric spectra of a reference fin structure of a Fin Field-effect transistor (FinFET) on reference semiconductor wafers are collected at a first checkpoint proximate to a selected processing step during fabrication of the reference semiconductor wafers (step 400). Reference measurements of the reference fin structure are collected at a second checkpoint proximate to a different processing step subsequent to the first checkpoint (step 402). A prediction model is trained by performing machine learning (ML) to identify correspondence between the scatterometric spectra and values based on the reference measurements (step 404). Scatterometric spectra of a production fin structure, corresponding to the reference fin structure, on a production semiconductor wafer are collected at the first checkpoint during fabrication of the production semiconductor wafer (step 406). A prediction value predictive of an expected measurement of the production fin structure at the second checkpoint is produced, preferably at the first checkpoint, using the prediction model based on the scatterometric spectra of the production fin structure collected at the first checkpoint (step 408). The expected measurement of the production fin structure is compared, preferably at the first checkpoint, with a predefined target measurement planned for the production fin structure at the second checkpoint (step 410). One or more process control parameters of any processing steps of the production fabrication process between the first and second checkpoints are adjusted to reduce any difference found between the expected measurement and the predefined target measurement (step 412).

Reference is now made to FIG. 5 which is a simplified flowchart illustration of an exemplary method of operation of the system of FIGS. 1A and 1B, operative in accordance with an alternative embodiment of the invention. In the method of FIG. 5, steps 400-408 of the method of FIG. 4 are performed, where the prediction value produced in step 408 is predictive of an expected fin height measurement of the production fin structure at the second checkpoint (step 500). The production scatterometric spectra are used to determine, preferably at the first checkpoint, the STI step height of the production fin structure (step 502). The expected measurement of the production fin structure is compared, preferably at the first checkpoint, with a predefined target fin height measurement planned for the production fin structure at the second checkpoint (step 504). A total etch amount is calculated by adding the expected fin height measurement to the STI step height (step 506). The total etch amount is converted to an etch time (step 508). If a difference is found between the expected fin height measurement and the predefined target fin height measurement, the etch time is adjusted in order to reduce the difference and thereby achieve the predefined target fin height measurement at the second checkpoint (step 510). One or more processing steps after the first checkpoint are controlled to implement the etch time in order to achieve the predefined target fin height measurement at the second checkpoint (step 512).

Reference is now made to FIG. 6 which is a simplified flowchart illustration of an exemplary method of operation of the system of FIGS. 1A and 1B, operative in accordance with an alternative embodiment of the invention. In the method of FIG. 6, steps 400-402 of the method of FIG. 4 are performed (step 600). The reference scatterometric spectra are used to determine, preferably at the first checkpoint, the STI step height of the reference fin structure (step 602). A total etch amount is calculated by adding the reference fin height measurement to the STI step height (step 604). A prediction model is trained by performing machine learning (ML) to identify correspondence between various scatterometric spectra and total etch amounts (step 606). Steps 406-408 of the method of FIG. 4 are performed, where the prediction value produced in step 408 is predictive of a total etch amount (step 608). The total etch amount is converted to an etch time and an expected fin height at the second checkpoint (step 610). The expected measurement of the production fin structure is compared, preferably at the first checkpoint, with a predefined target fin height measurement planned for the production fin structure at the second checkpoint (step 612). If a difference is found between the expected fin height measurement and the predefined target fin height measurement, the etch time is adjusted in order to reduce the difference and thereby achieve the predefined target fin height measurement at the second checkpoint (step 614). One or more processing steps after the first checkpoint are controlled to implement the etch time in order to achieve the predefined target fin height measurement at the second checkpoint (step 616).

The flowchart illustrations and block diagrams in the drawing figures illustrate the architecture, functionality, and operation of possible implementations of systems, methods, and computer program products according to various embodiments of the invention. In this regard, each block in the flowchart illustrations or block diagrams may represent a module, segment, or portion of computer instructions, which comprises one or more executable computer instructions for implementing the specified logical function(s). In some alternative implementations, the functions noted in a block may occur out of the order noted in the drawing figures. For example, two blocks shown in succession may, in fact, be executed substantially concurrently, or the blocks may sometimes be executed in the reverse order, depending upon the functionality involved. It will also be noted that each block of the flowchart illustrations and block diagrams, and combinations of such blocks, can be implemented by special-purpose hardware-based and/or software-based systems that perform the specified functions or acts.

The descriptions of the various embodiments of the invention have been presented for purposes of illustration, but are not intended to be exhaustive or limited to the embodiments disclosed. For example, the systems and methods described herein are applicable to any type of structure on semiconductor wafers. Many modifications and variations will be apparent to those of ordinary skill in the art without departing from the scope and spirit of the described embodiments.

What is claimed is:

1. A computer-implemented method for use in process control during manufacture of semiconductor devices on semiconductor wafers, the method comprising:
collecting scatterometric spectra of a reference fin structure of a FinFET on a reference semiconductor wafer at a first checkpoint proximate to a first processing step during fabrication of the reference semiconductor wafer;
collecting reference measurements of the reference fin structure at a second checkpoint proximate to a second processing step during the fabrication of the reference semiconductor wafer, wherein the second checkpoint is subsequent to the first checkpoint; and
performing machine learning to identify correspondence between the scatterometric spectra and values based on the reference measurements, thereby training a prediction model for producing a prediction value associated with a production fin structure of the FinFET on a production semiconductor wafer based on scatterometric spectra of the production fin structure collected at a first checkpoint during fabrication of the production semiconductor wafer,
wherein the production fin structure corresponds to the reference fin structure, and
wherein the first checkpoint during the fabrication of the production semiconductor wafer corresponds to the first checkpoint during the fabrication of the reference semiconductor wafer.

2. The method according to claim 1 and further comprising:
collecting the scatterometric spectra of the production fin structure at the first checkpoint during the fabrication of the production semiconductor wafer; and
producing, using the prediction model, the prediction value associated with the production fin structure based on scatterometric spectra of the production fin structure.

3. The method according to claim 2 and further comprising producing the prediction value at the first checkpoint during the fabrication of the production semiconductor wafer.

4. The method according to claim 2 wherein the prediction value is predictive of an expected measurement of the production fin structure at a second checkpoint during the fabrication of the production semiconductor wafer corresponding to the second checkpoint during the fabrication of the reference semiconductor wafer.

5. The method according to claim 4 and further comprising:
comparing the expected measurement with a predefined target measurement planned for the production fin structure at the second checkpoint during the fabrication of the production semiconductor wafer; and
adjusting a process control parameter of a processing step subsequent to the first checkpoint during the fabrication of the production semiconductor wafer and prior to the second checkpoint during the fabrication of the production semiconductor wafer, to reduce a difference between the expected measurement and the predefined target measurement.

6. The method according to claim 5 wherein the comparing comprises comparing at the first checkpoint during the fabrication of the production semiconductor wafer.

7. The method according to claim 5 wherein the adjusting comprises providing input to a semiconductor manufacturing tool for controlling operation of the semiconductor manufacturing tool during the fabrication of the production semiconductor wafer.

8. The method according to claim 1 wherein the performing machine learning comprises identifying the correspondence between the scatterometric spectra and the values based on the reference measurements where predefined statistical criteria are met indicating that any of the scatterometric spectra of the reference fin structure at the first checkpoint are statistically linked to any of the values based on the reference measurements of the reference fin structure at the second checkpoint.

9. The method according to claim 1 wherein the fabrication of the production semiconductor wafer and the production fin structure uses a process identical to a process used to fabricate the reference semiconductor wafer and the reference fin structure, wherein the first and second checkpoints during the fabrication of the production semiconductor wafer correspond, respectively, to the first and second checkpoints during the fabrication of the reference semiconductor wafer.

10. The method according to claim 4 and further comprising:
determining, using the scatterometric spectra of the production fin structure, a height difference between a top of the production fin structure and a top of a silicon oxide layer above a trench adjacent to the production fin structure;
calculating a total etch amount by adding the expected measurement to the height difference;
converting the total etch amount to an etch time; and
controlling one or more processing steps after the first checkpoint during the fabrication of the production semiconductor wafer to implement the etch time in order to achieve a predefined target measurement planned for the production fin structure at the second checkpoint during the fabrication of the production semiconductor wafer, wherein the expected measurement and the predefined target measurement are of height of the production fin structure.

11. The method according to claim 10 and further comprising:
comparing the expected measurement with the predefined target measurement; and
adjusting the etch time to reduce a difference between the expected measurement and the predefined target measurement.

12. The method according to claim 1 and further comprising:
determining, using the scatterometric spectra of the reference fin structure, a height difference between a top of the reference fin structure and a top of a silicon oxide layer above a trench adjacent to the reference fin structure, wherein the reference measurement is of height of the reference fin structure;
calculating a total etch amount by adding the reference measurement to the height difference, wherein the total etch amount is used as one of the values based on the reference measurements used to train the prediction model;
collecting the scatterometric spectra of the production fin structure at the first checkpoint during the fabrication of the production semiconductor wafer;
producing, using the prediction model, the prediction value representing a total etch amount associated with the production fin structure based on scatterometric spectra of the production fin structure;
converting the total etch amount to an etch time; and
controlling one or more processing steps after the first checkpoint during the fabrication of the production semiconductor wafer to implement the etch time in order to achieve a predefined target measurement at the second checkpoint during the fabrication of the reference semiconductor wafer, wherein the predefined target measurement is of height of the production fin structure.

13. The method according to claim 12 and further comprising:
determining an expected fin height at the second checkpoint from the etch time;
comparing the expected fin height with the predefined target measurement; and
adjusting the etch time to reduce a difference between the expected fin height and the predefined target measurement.

14. A system for use in process control during manufacture of semiconductor devices on semiconductor wafers, the system comprising:
a spectrum acquisition tool configured to collect scatterometric spectra of a reference fin structure of a FinFET on a reference semiconductor wafer at a first checkpoint proximate to a first processing step during fabrication of the reference semiconductor wafer;
a reference tool configured to collect reference measurements of the reference fin structure at a second checkpoint proximate to a second processing step during the fabrication of the reference semiconductor wafer, wherein the second checkpoint is subsequent to the first checkpoint; and
a training unit configured to perform machine learning to identify correspondence between the scatterometric spectra and values based on the reference measurements, thereby training a prediction model for producing a prediction value associated with a production fin structure of the FinFET on a production semiconductor wafer based on scatterometric spectra of the production fin structure collected at a first checkpoint during fabrication of the production semiconductor wafer,
wherein the production fin structure corresponds to the reference fin structure, and
wherein the first checkpoint during the fabrication of the production semiconductor wafer corresponds to the first checkpoint during the fabrication of the reference semiconductor wafer.

15. The system according to claim 14 wherein the spectrum acquisition tool is configured to collect the scatterometric spectra of the production fin structure at the first checkpoint during the fabrication of the production semiconductor wafer, and further comprising a prediction unit configured to produce, using the prediction model, the prediction value associated with the production fin structure based on scatterometric spectra of the production fin structure.

16. The system according to claim 15 wherein the prediction unit is configured to produce the prediction value at the first checkpoint during the fabrication of the production semiconductor wafer.

17. The system according to claim 15 wherein the prediction value is predictive of an expected measurement of the production fin structure at a second checkpoint during the fabrication of the production semiconductor wafer corresponding to the second checkpoint during the fabrication of the reference semiconductor wafer.

18. The system according to claim 17 and further comprising a process control unit configured to
compare the expected measurement with a predefined target measurement planned for the production fin structure at the second checkpoint during the fabrication of the production semiconductor wafer, and
adjust a process control parameter of a processing step subsequent to the first checkpoint during the fabrication of the production semiconductor wafer and prior to the second checkpoint during the fabrication of the production semiconductor wafer, to reduce a difference between the expected measurement and the predefined target measurement.

19. The system according to claim 14 wherein the training unit is configured to perform the machine learning to identify the correspondence between the scatterometric spectra and the values based on the reference measurements where predefined statistical criteria are met indicating that any of the scatterometric spectra of the reference fin structure at the first checkpoint are statistically linked to any of the values based on the reference measurements of the reference fin structure at the second checkpoint.

20. The system according to claim 17 wherein
the spectrum acquisition tool is configured to determine, using the scatterometric spectra of the production fin structure, a height difference between a top of the production fin structure and a top of a silicon oxide layer above a trench adjacent to the production fin structure, and
the process control unit is configured to
calculate a total etch amount by adding the expected measurement to the height difference,
convert the total etch amount to an etch time, and
control one or more processing steps after the first checkpoint during the fabrication of the production semiconductor wafer to implement the etch time in order to achieve a predefined target measurement planned for the production fin structure at the second checkpoint during the fabrication of the production semiconductor wafer, wherein the expected measurement and the predefined target measurement are of height of the production fin structure.

21. The system according to claim 14 wherein
the spectrum acquisition tool is configured to determine, using the scatterometric spectra of the reference fin structure, a height difference between a top of the reference fin structure and a top of a silicon oxide layer above a trench adjacent to the reference fin structure, wherein the reference measurement is of height of the reference fin structure,
the training unit is configured to use a total etch amount as one of the values based on the reference measurements used to train the prediction model, wherein the total etch amount is calculated by adding the reference measurement to the height difference,
the spectrum acquisition tool is configured to collect the scatterometric spectra of the production fin structure at the first checkpoint during the fabrication of the production semiconductor wafer,
the prediction unit is configured to produce, using the prediction model, the prediction value representing a total etch amount associated with the production fin structure based on scatterometric spectra of the production fin structure, and
the process control unit is configured to
convert the total etch amount to an etch time, and
control one or more processing steps after the first checkpoint during the fabrication of the production semiconductor wafer to implement the etch time in order to achieve a predefined target measurement at the second checkpoint during the fabrication of the reference semiconductor wafer, wherein the predefined target measurement is of height of the production fin structure.

22. The system according to claim 21 wherein the process control unit is configured to
determine an expected fin height at the second checkpoint from the etch time,
compare the expected fin height with the predefined target measurement, and
adjust the etch time to reduce a difference between the expected fin height and the predefined target measurement.
